(19) United States
(12) Patent Application Publication
(10) Pub. No.: US 2009/0312971 A1
(43) Pub. Date: Dec. 17, 2009

(54) APPARATUS AND METHOD FOR LOCATING INFERIOR PARTS IN POWER DISTRIBUTION LINE EQUIPMENT BASED ON VARIATION OF RADIO FREQUENCY NOISE SIGNAL

(76) Inventor: Hyun-Chang Lee, Gangdong-gu (KR)

Correspondence Address: SHERR & VAUGHN, PLLC, 620 HERNDON PARKWAY, SUITE 320, HERNDON, VA, 20170, US

(21) Appl. No.: 12/483,374

(22) Filed: Jun. 12, 2009

(30) Foreign Application Priority Data
Jun. 12, 2008 (KR) 10-2008-0055257

(51) Int. Cl. G06F 19/00; G01R 23/16; G01S 1/00; G06F 15/00

(52) U.S. Cl. 702/77; 342/357.09; 702/76; 702/182

(57) ABSTRACT

An apparatus for locating inferior parts in distribution line equipment may include a wireless noise receiver for continually receiving multiple noise-free frequencies and converting the received multiple noise-free frequencies into an audio frequency signal, a signal processor for quantifying a power frequency and harmonic frequencies of the audio frequency signal, a signal analyzer for calculating variation of the power frequency and the harmonic frequencies, determining the number of changed frequencies based on the calculated variation, detecting a radio frequency noise signal generated from an inferior part based on the calculated variation and the number of changed frequencies, and a frequency calibrator for determining a noise-free band, selecting the multiple noise-free frequencies from the noise-free band, and managing a list of the selected multiple noise-free frequencies.

The present application claims priority under 35 U.S.C. 119 and 35 U.S.C. 365 to Korean Patent Application No. 10-2008-0055257 (filed on Jun. 12, 2008), which is hereby incorporated by reference in its entirety.

### BACKGROUND

A system for locating inferior parts in power distribution line equipment has been receiving attention in the power distribution industry. This system collects radio frequency (RF) noise signals emitted from power distribution line equipment while maintenance person travel along live power distribution lines on foot or by vehicle and locates inferior parts by diagnosing the collected RF noise signals.

An apparatus and method for locating inferior parts in power distribution line equipment should be capable of detecting the insulation degradation on the surface of covered conductor usually situated on top of the post insulator which generates a very weak RF noise signal compared to the RF noise signal generated from gap arc discharge. The system is also capable of detecting RF noise signals generated by corona discharge of an insulator regardless of weather conditions.

An electric service provider has been using polyethylene insulated covered conductor instead of bare aluminum electric wire to reduce defects caused by corrosion of the power cable, and to reduce temporary interruption of electric power caused by objects such as trees or birds contacting the power cable. FIG. 4 shows a polyethylene insulated covered conductor.

The polyethylene insulated covered conductor may prevent defects and corrosion, but also has shortcomings. Since an electric field is formed uneven voltage distribution over the surface of covered conductor, voltage may be concentrated at a particular location when an excessive voltage stress is generated by lightning or by fault current. It may cause arc discharge as shown in FIG. 5.

Strong electric shocks damage spots of surface by heat and peel off the polyethylene cover from conductive metal to lead the bare wire exposed to the air. After become victim of voltage shock, the spots become the current sources to the ground through the surface tracking path on the post insulator and exposed metal conductor will be oxidized and weaken mechanically as shown in inferior parts (1) and (3) of FIG. 1. Such a damaged power cable may be torn, even by small external forces such as strong wind or lightning.

On a windy day, a mechanically weaken covered conductor could be torn easily by strong wind and fallen down to ground or lay on the tree without tripping the circuit breaker because of high ground impedance. This may cause a serious problems.

In the case of non tripped live wire is on the street or on the tress, the harmful high voltage charge can be dangerous to pedestrian and assets. Furthermore this charged voltage over the tree can cause serious wildfire on the mountain in dry season. It may cause loss of life and property.

Contrary to its serious of future harm to life and property, such inferior parts from the weak spots of covered conductor wire generate a very weak RF signal. For example, FIG. 7 shows an RF signal generated from an inferior part from the mechanically weakened covered conductor. As shown, this RF signal is very weak compared to an RF signal generated from an inferior part generating gap discharge, which is shown in FIG. 6.

Although a system according to the related art is capable of detecting a strong RF signal that may be generated from arcing between a short gap, the system according to the related art is incapable of accurately detecting a weak RF signal that may be generated from peeled off parts 1 and 2 of a power cable, big gaps 2, 4, 5, and 6 formed at the sides of an insulator, and an inferior part 7 generating weak corona discharge, for example, an inside of bushing of load switch, as shown in FIGS. 1, 2, and 3.

FIG. 1 is a picture showing a peeled off insulated of a power cable over a line post insulator or a broken part of an insulator. FIG. 2 shows a broken part on a skirt of a suspension insulator. FIG. 3 is a picture showing an inferior part of a bushing of load switch that generates an RF noise signal.

FIG. 5 is a diagram for describing arc generation from a peeled off insulation of a power cable over a line post insulator.

The components in the overhead power distribution system are covered by protective insulation coatings but they are outside and pollutants such as dust or chemical particles are generally attached to the surface of the insulation coating. The variation of moisture level between the particle of pollutants changes impedance of tracking path and change the power and frequency of RF noise signal. The environmental factors which can affect the RF noise characteristic would be moisture from dew, rain, snow, and water particles in the atmosphere and wind direction toward the pollutants.

For example, since the air temperature is low in the morning, moisture such as dew or fog is generally formed. Such moisture soaks the particles of dust on the insulators to maintain low impedance path to pass the arc current originated from peeled spot of conductor to the ground even under normal distribution voltage level. It can generate the tracking arc noise under heavy moisture level usually in the late night to early morning, but direct sun light heat and wind remove the moisture on the insulator to cause the easy dry-band corona between the air gap.

When the air temperature generally increases. Due to the increased temperature, moisture in a gap is evaporated and electricity is discharged between the air gap. Although surface tracking discharge is reduced because a water layer forming an electricity path is also evaporated, corona discharge is weakly generated at a point where electric field is concentrated. Therefore, a weak radio frequency noise signal is generated.

Due to the characteristics of RF noise signals, a inferior parts in the power distribution line may or may not generate an RF noise signal depending on weather conditions and humidity.

There is a limitation in detecting such a emitting signals from insulation degraded components irrespective of signal level using a constant threshold value as shown in FIGS. 6 and 7. FIG. 6 is a graph showing a radio frequency noise signal generated from a gap generating arc, and FIG. 7 is a graph showing a radio frequency noise signal generated from an inferior part generating tracking discharge.

As shown in FIG. 6, a detection range may be set based on an upper threshold value 11 and a lower threshold value 12. An inferior part 10 of power distribution line equipment may be detected if a detected RF noise signal exceeds the detection range.

Since a signal level is low in FIG. 7, a detection range from an upper threshold value 16 to a lower threshold value 17 may become narrow. An inferior part 15 is determined based on the detection range of FIG. 7.

These threshold values should be dynamically changed depending on factors such as weather conditions and external particles. For example, in order to detect a weak RF noise signal, a threshold value should be set low. In this case, accuracy in detecting an inferior part decreases because a system may wrongly determine all power distribution line equipment as inferior parts in a strong signal area. In case of increasing a threshold value, a system may not detect an inferior part generating a weak signal. However, it is impossible to change the threshold values depending on conditions whenever the conditions are changed.

In view of power line maintenance, it is necessary to carefully observe a covered conductor to locate the faulty or ongoing mechanical weakened spots hidden by surroundings even on a day with good weather (dry) conditions. However, there is a limitation in detecting such a weak radio frequency noise signal generated from a faulty spots on the covered conductor using known diagnosing systems according to a related art.

### SUMMARY

Embodiments relate to an apparatus and method for locating inferior part of power distribution line equipment through comparing variation of radio frequency noise signals.

Embodiments related to an apparatus for locating inferior parts of distribution line equipment which may include a wireless noise receiver for finding environmental radio frequencies at a predetermined patrol planning area and unique RF noise frequencies emitted from each power distribution lines before patrolling

Continuously monitor multiple noise-free frequencies selected from a noise-free band while patrolling the power distribution lines in the predetermined patrol planning area, converting the received signals into audio frequency signals, a signal processor for quantifying a power frequency and harmonic frequencies in the audio frequency signals, a signal analyzer for calculating variation level of the power frequency and the harmonic frequencies by comparing the signal levels of the power frequency and the harmonic frequencies from a previously received multiple tuned RF signals, determining the number of changed frequencies based on the calculated variation, detecting a radio frequency noise signal generated from an inferior part of the power distribution line equipment based on the calculated variation and the number of changed frequencies, and a frequency calibrator to manage the noise-free frequency spectrum bandwidth out of occupied frequencies and select the frequencies from noise-free spectrum bands and switch the frequency(ies) to the new one(s) if any of selected frequency or frequencies has(have) continuing noises without variation by giving the list of monitoring frequencies to the receiver and change to the new frequency(ies) whenever needed

In accordance with embodiments, the signal processor may include a low pass filter for filtering the audio frequency signal from the wireless noise receiver to pass frequencies signals lower than 800 Hz, and a Fast Fourier Transform unit for dividing the filtered signal from the low pass filter into the power frequency and the harmonic frequencies. The power frequency may be one of 50 Hz and 60 Hz and the harmonic frequencies may include second, third, fourth, and fifth harmonic frequencies.

In accordance with embodiments, the frequency calibrator may group the multiple noise-free radio frequency signals selected from the noise-free band into a monitoring group, and continually monitor the monitoring group to switch to new frequencies when needed.

In accordance with embodiments, the apparatus may further include a radio frequency/audio frequency controller for synchronizing a radio frequency signal with an audio frequency signal, receiving information on the selected multiple noise-free frequencies from the frequency calibrator, and controlling noise-free frequencies to monitor by transmitting a radio frequency signal selection command to the wireless noise receiver, and a global positioning signal receiver to display the measured data on the moving map while patrolling power distribution lines.

Embodiments relate to a method for locating an inferior part in power distribution line equipment, which may include noise-free frequency spectrum bandwidths information to select and monitor the most silent frequencies in the area to catch the weaker signals from the power lines and avoid the unique characteristic frequencies to be tuned by scanning the noises in the pre-selected environmental noise-free bandwidth at the beginning point and direct under the patrol planned distribution line

The receiver will have signal analyzing functions to detect the amplitude modulated type noise signals emitted from normal power distribution line equipment in the predetermined patrol planning area, selecting multiple noise-free frequencies, and continually monitoring the selected multiple noise-free frequencies, continually receiving the selected multiple noise-free radio frequency signals, converting the received multiple noise-free radio frequency signals to an audio frequency signal, quantifying a power frequency and harmonic frequencies of the audio frequency signals, calculating variation of the power frequency and the harmonic frequencies by comparing the signal levels of the power frequency and the harmonic frequencies with signal levels of a power frequency and harmonic frequencies of an audio frequency signal converted from a previously received noise-free RF signal, determining the number of changed frequencies based on the calculated variation, detecting a radio frequency noise signal generated from an inferior part of the power distribution line equipment based on the calculated variation and the number of changed frequencies, and selectively performing a fine search mode and a directional search mode when the inferior part is detected.

In accordance with embodiments, the continually received radio frequency signals may be selected from a noise-free band which is not occupied by environmental radio frequency noise signals in the region and unique characteristic radio frequency noise signals from the patrol planned distribution line.

In accordance with embodiments, in said detecting inferior parts in power distribution line equipment, the received multiple noise-free radio frequency signals may be demodulated to an audio frequency signal, the audio frequency signal may be filtered to pass a frequency signal lower than approximately 800 Hz, the filtered audio frequency signal may be divided into a power frequency, second, third, fourth, and fifth harmonic frequencies, variation of the power frequency, and the second, third, fourth, and fifth harmonic frequencies may be calculated by comparing signal levels of the power frequency, and the second, third, fourth, and fifth harmonic frequencies with signal levels of a power frequency and harmonic frequencies of an audio frequency signal converted from previously received noise-free radio frequency signals, the number of changed frequencies in the power frequency, and second, third, fourth, and fifth harmonic frequencies may be determined based on the calculated variation, and the inferior parts may be detected based on the calculated variation and the number of the changed frequencies. The power frequency may be one of 50 Hz and 60 Hz.

In accordance with embodiments, in said detecting inferior parts in power distribution line equipment, the received multiple noise-free radio frequency signals may be demodulated to an audio frequency signal, the audio frequency signal may be filtered to pass frequency signals lower than approximately 800 Hz, the filtered audio frequency signal may be divided into a power frequency, second, third, fourth, and fifth harmonic frequencies, variation of a the power frequency, and the second, third, fourth, and fifth harmonic frequencies may be calculated by calculating an occupancy rate of a sum of signal levels of the power frequency and the first, third, fourth, and fifth harmonic frequencies and a signal level of the filtered audio frequency signal and comparing the calculated occupancy rate with an occupancy rate of a power frequency and harmonic frequencies of an audio frequency signal converted from previously received noise-free radio frequency signals, the number of changed frequencies in the power frequency, and second, third, fourth, and fifth harmonic frequencies may be determined based on the calculated variation, and the inferior parts may be detected based on the calculated variation and the number of the changed frequencies. The power frequency may be one of 50 Hz and 60 Hz.

In accordance with embodiments, a direction to an inferior art may be detected by simultaneously receiving a frequency signal having a strongest signal level through a plurality of antennas or through rotating a rotational antenna and comparing the received frequency signals to each other. The plurality of antennas may be disposed toward different directions.

In accordance with embodiments, an inferior part may be detected by continually monitoring a frequency signal having a highest signal level in a suspected inferior part area and comparing the continually monitored frequency signals.

In accordance with embodiments, said sequentially scanning radio frequency signals in a predetermined band may include determining an RF noise band occupied by the environmental RF noise signals of the patrol planning area at a location in distance from power distribution lines in the patrol planning area, determining an amplitude modulated noise band occupied by amplitude modulated noise signals emitted from power distribution lines in the patrol planning area at a location close to the power distribution lines, and determining a noise-free band higher than approximately 1 MHz which is not occupied by the environmental RF noise signals and the amplitude modulated noise signals during said determining an RF noise band and said determining an amplitude modulated noise band, and determining whether the noise-free band is in a public band or not.

### DRAWINGS

FIG. 1 is a picture showing a peeled off insulation of a power cable over a line post insulator or a broken part of an insulator.

FIG. 2 is a picture showing a broken part on a skirt of a suspension insulator.

FIG. 3 is a picture showing an inferior part of a switch bushing that generates an RF noise signal.

FIG. 4 is a diagram illustrating an insulated power cable.

FIG. 5 is a diagram for describing arc generation from a peeled off insulated of a power cable over a line post insulator.

FIG. 6 is a graph showing a radio frequency noise signal generated from a gap generating arc.

FIG. 7 is a graph showing a radio frequency noise signal generated from an inferior part generating corona discharge.

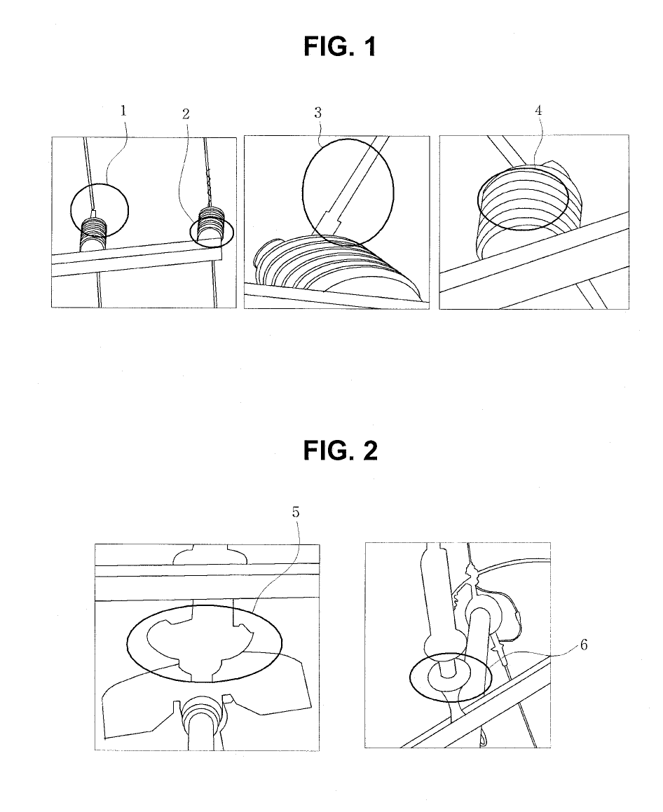

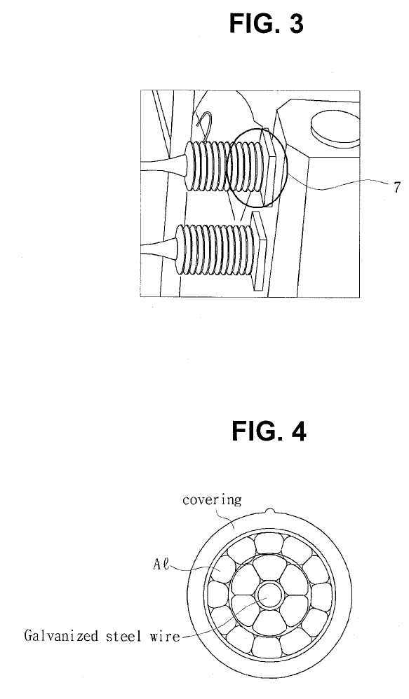

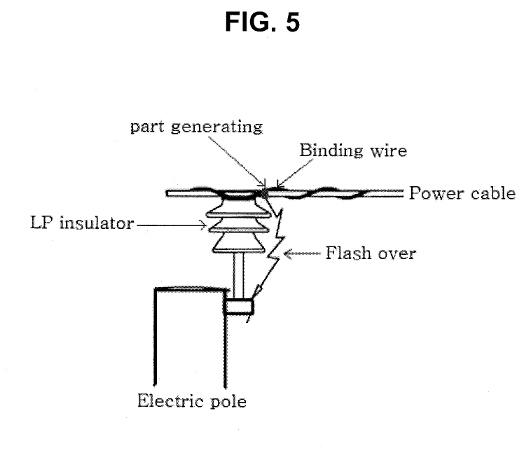

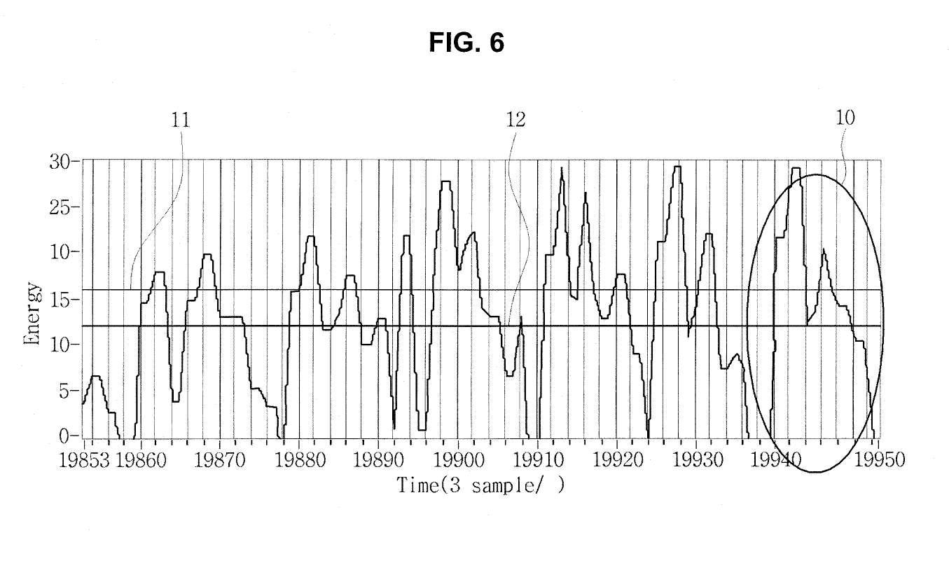

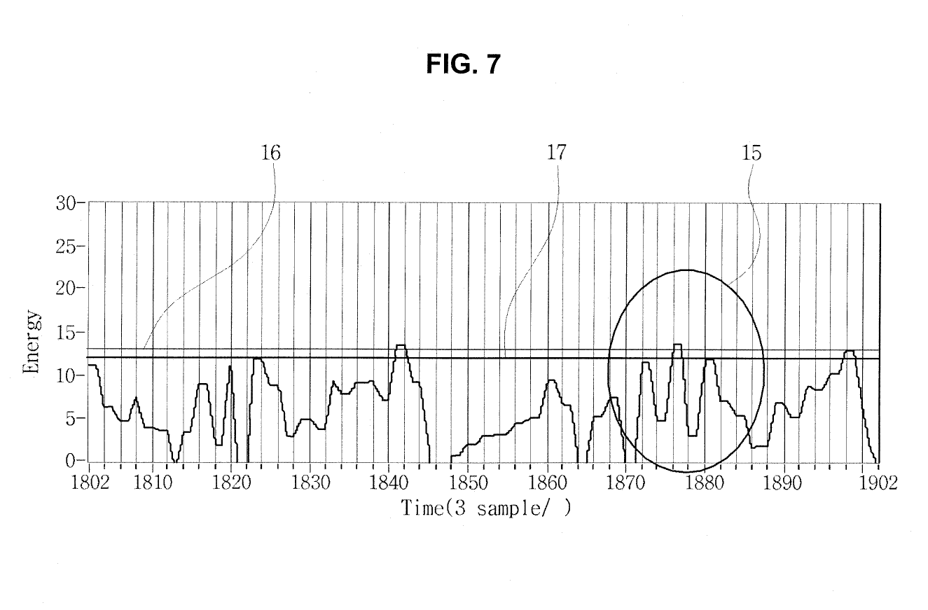

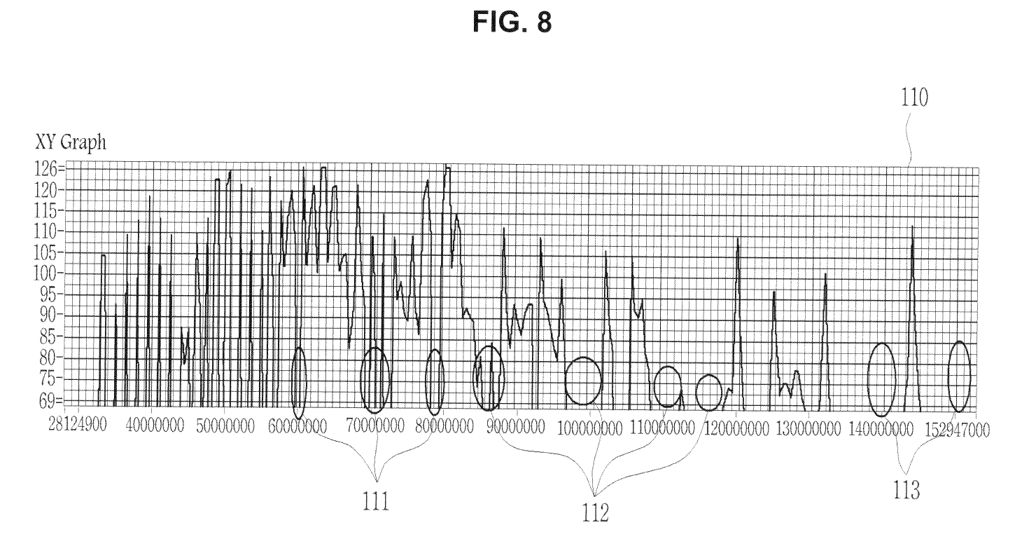

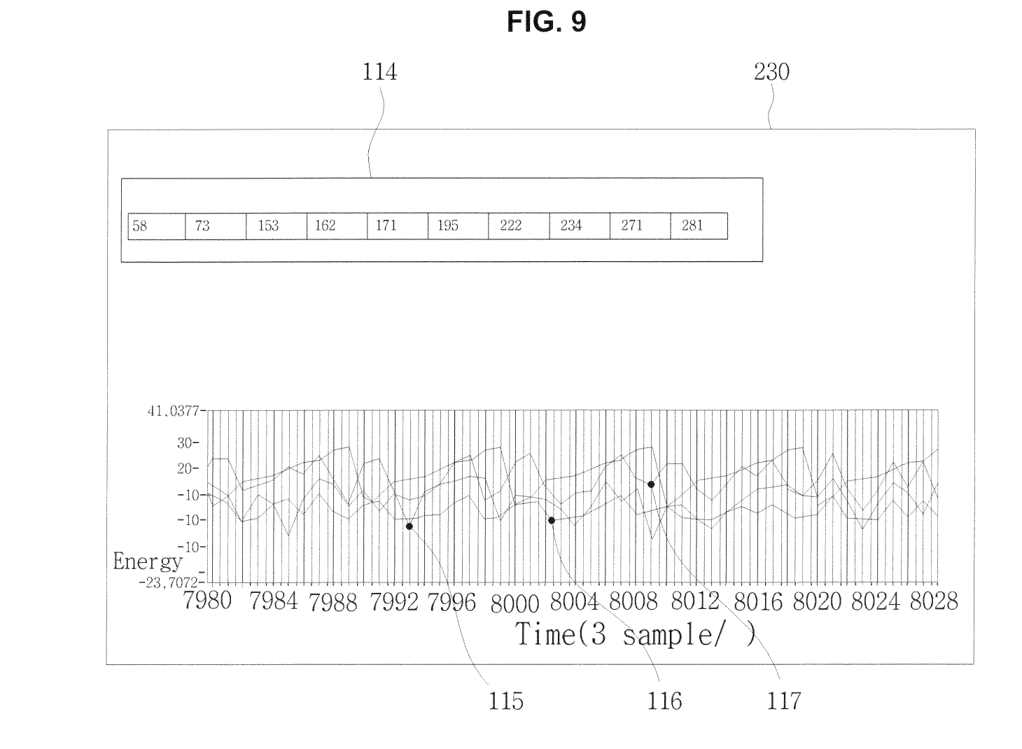

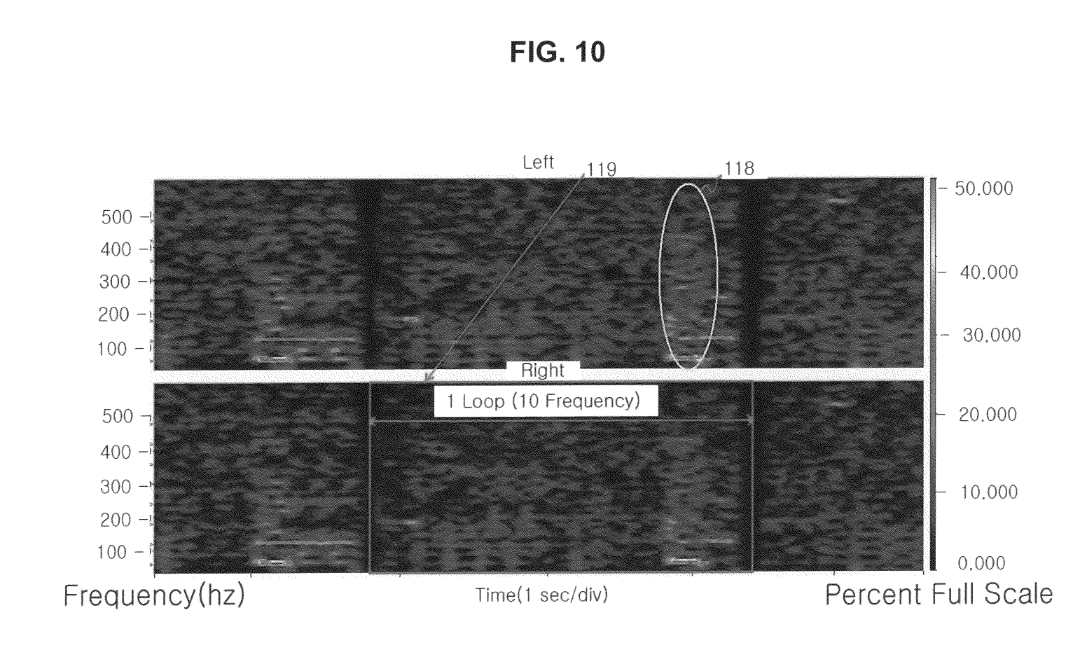

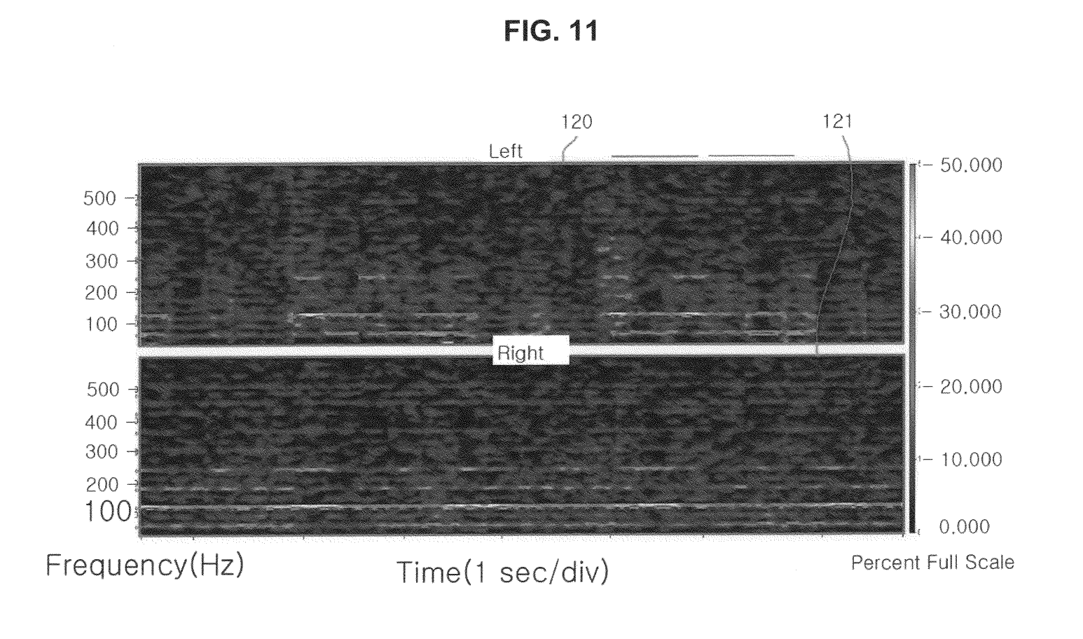

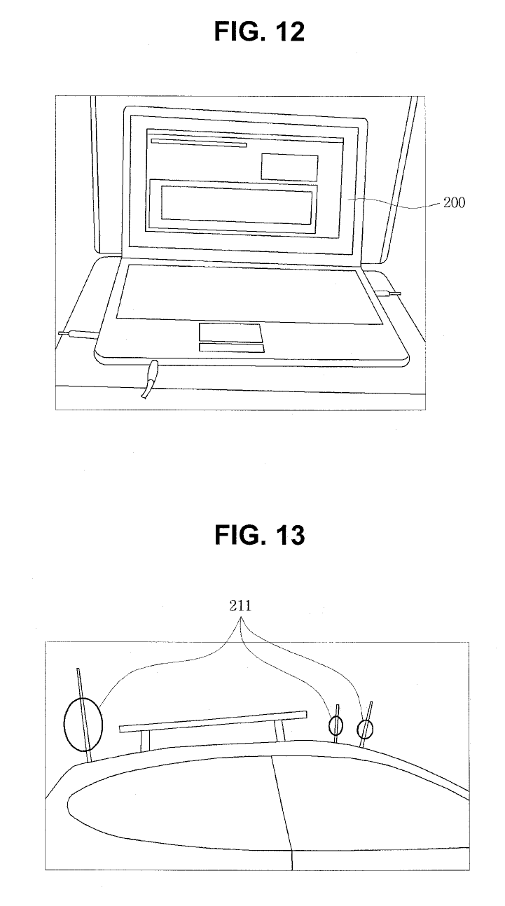

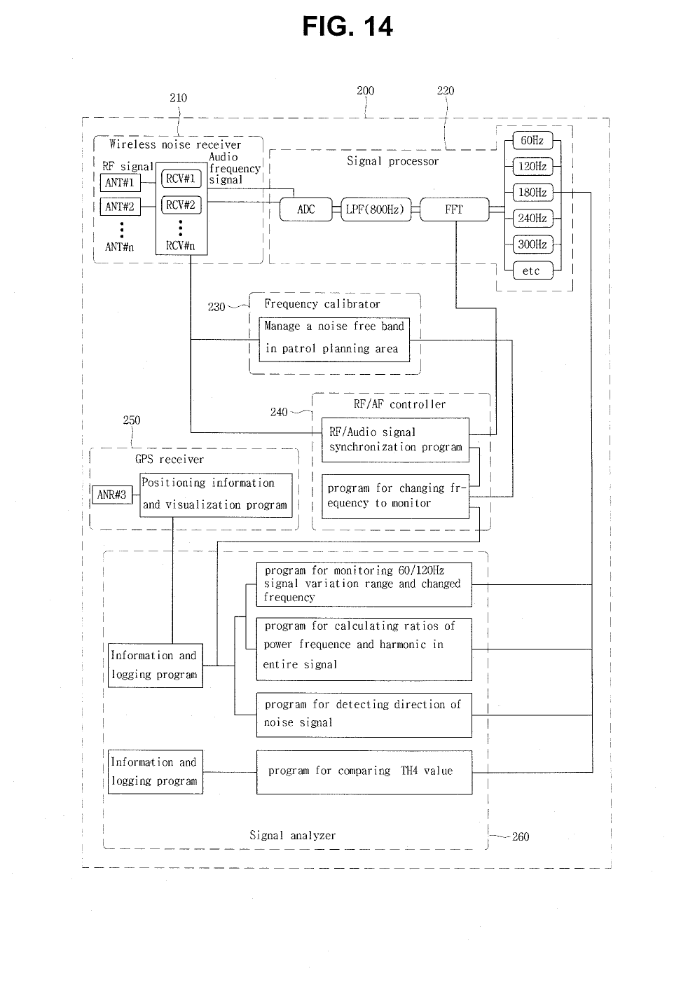

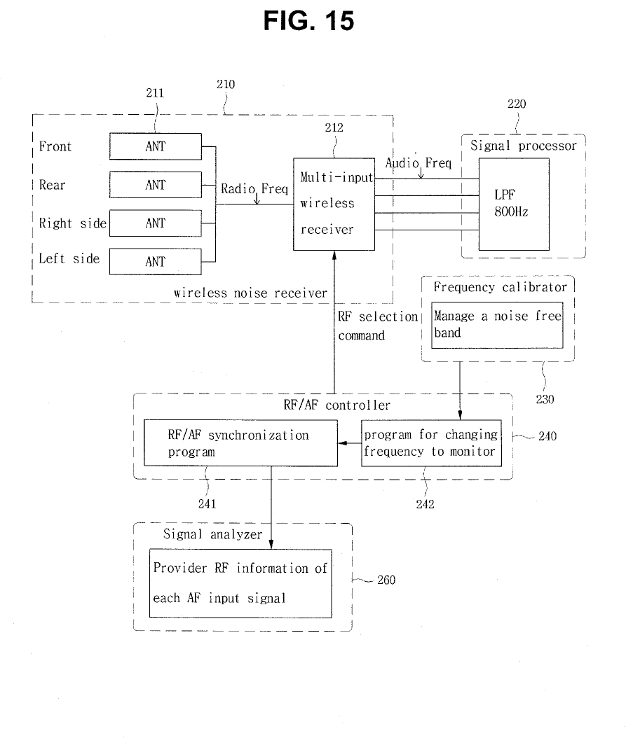

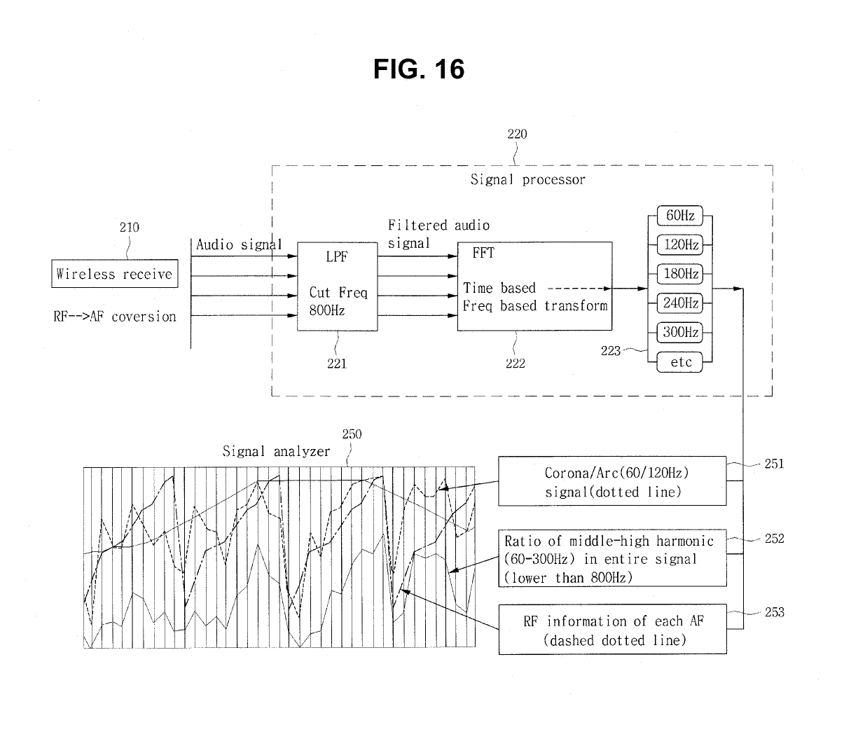

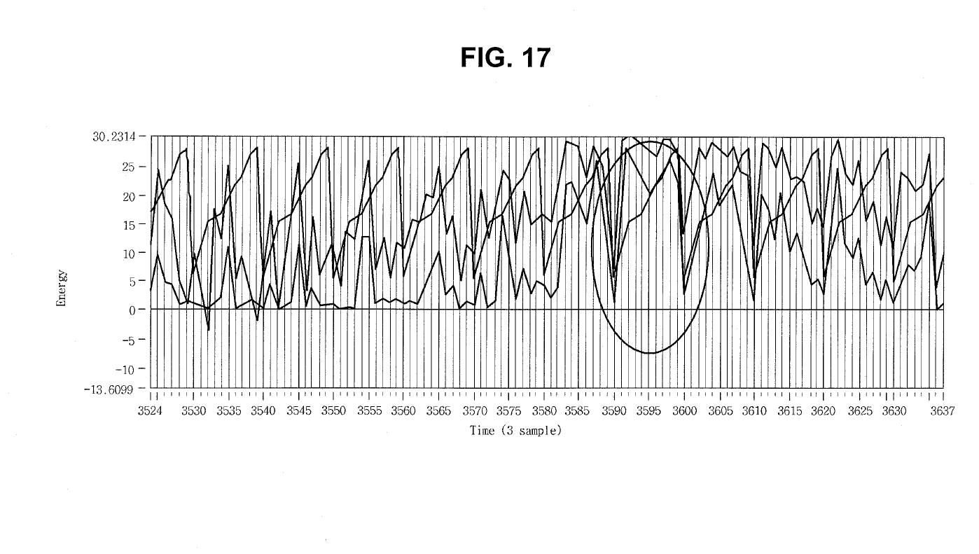

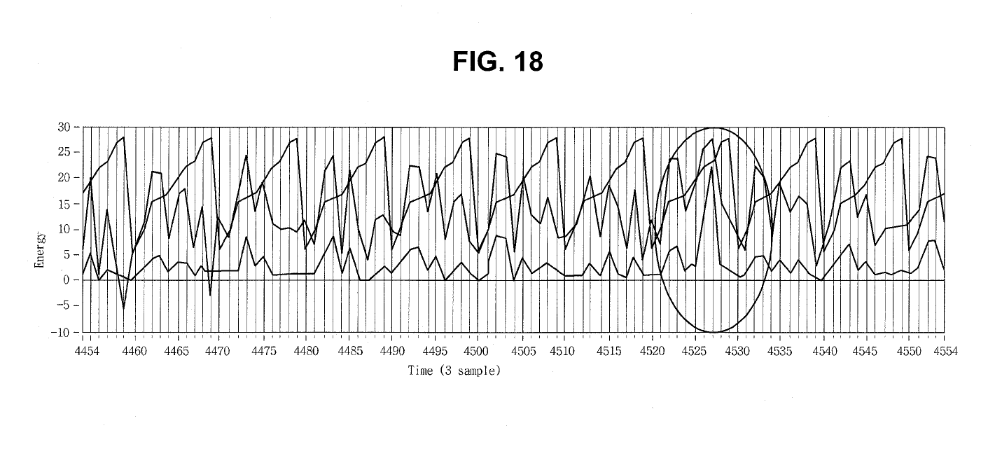

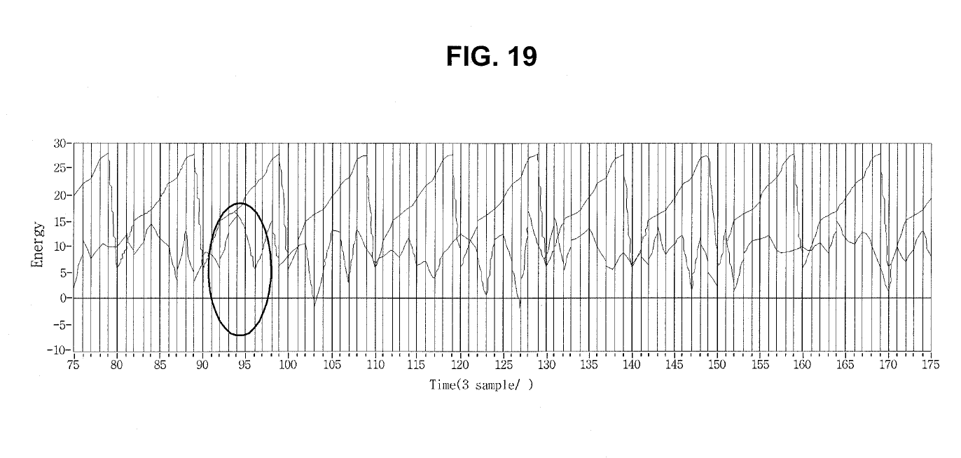

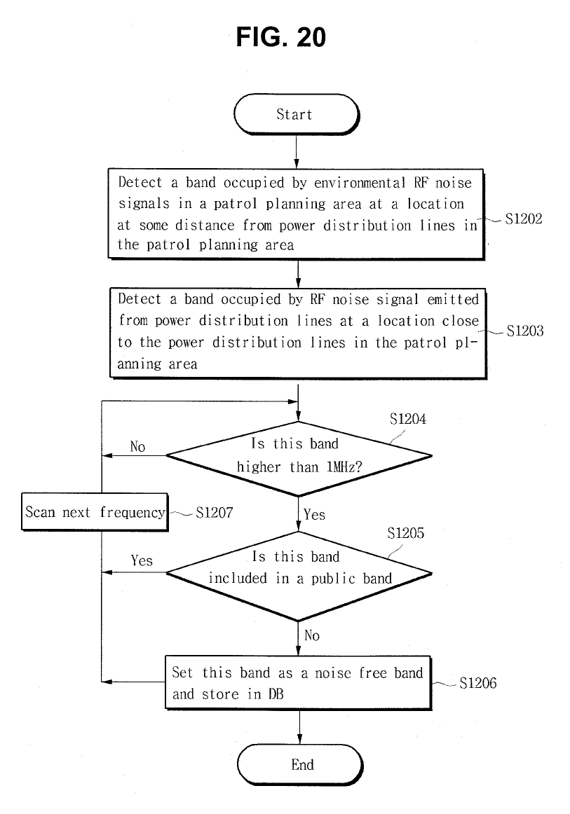

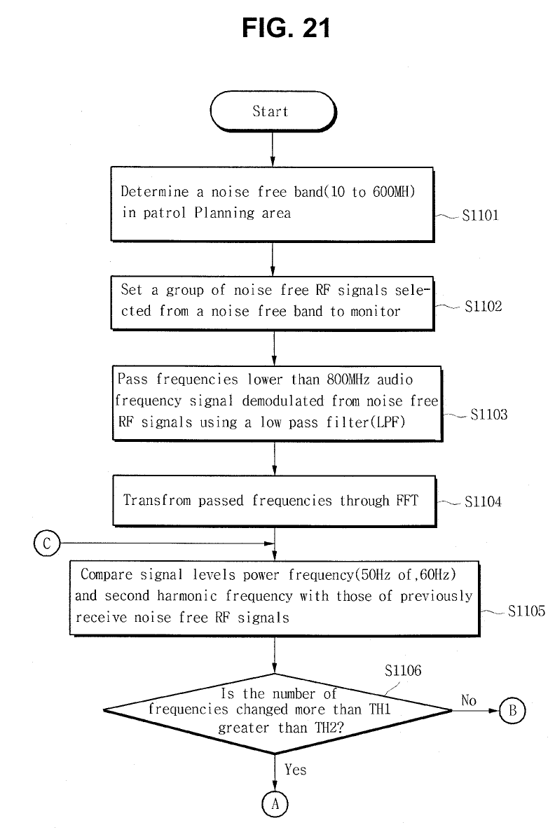

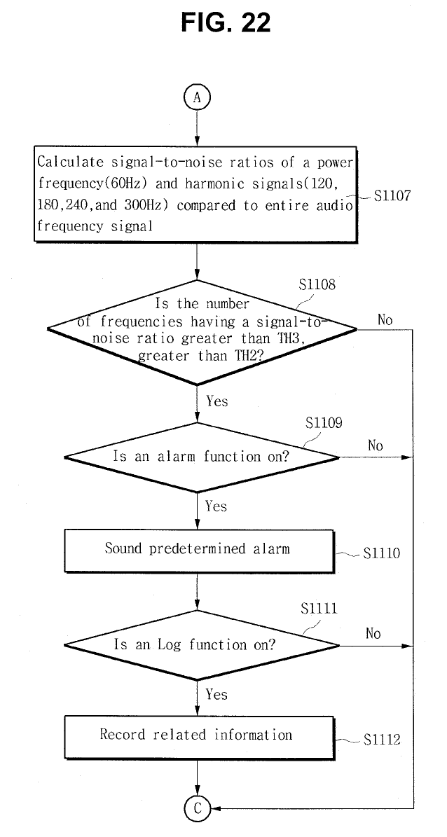

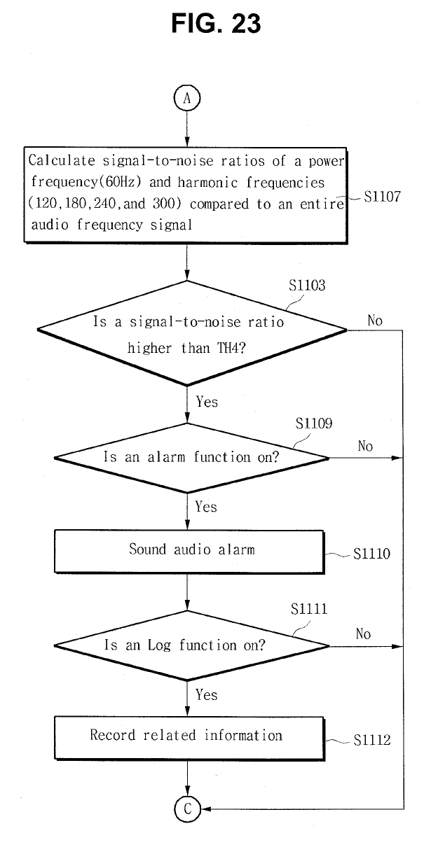

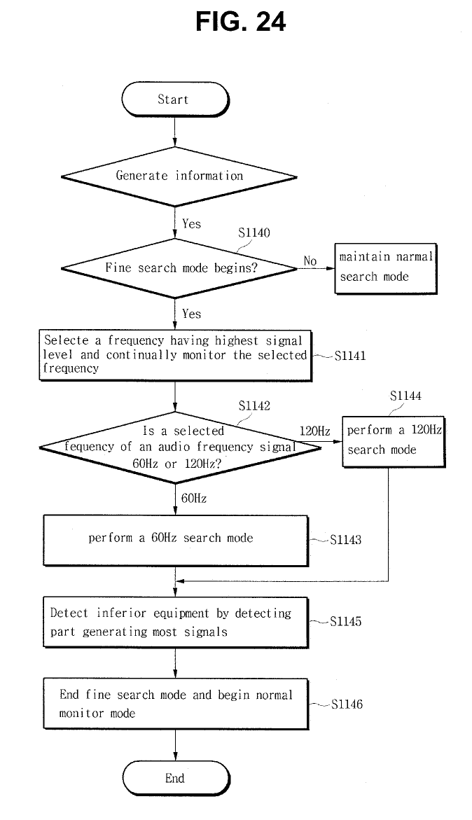

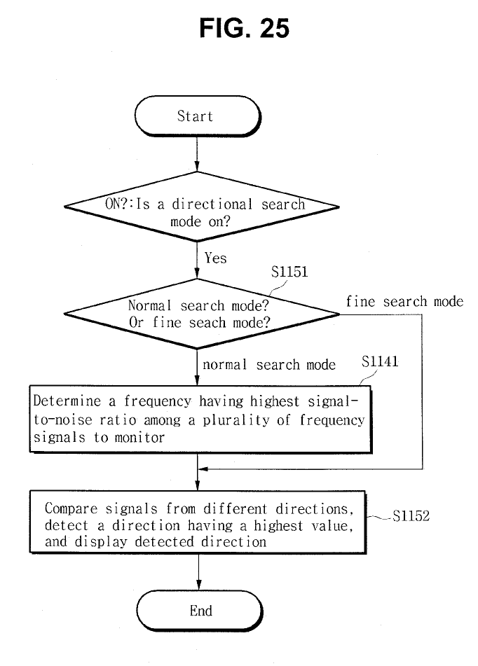

Example FIG. 8 is a diagram illustrating a frequency calibration program of an apparatus for locating inferior parts in power distribution line equipment in accordance with embodiments.

Example FIG. 9 is a graph showing a harmonic frequency occupancy rate and comparison of a 60 Hz signal and a 120 Hz signal.

Example FIG. 10 illustrates a signal spectrogram for a directional search mode.

Example FIG. 11 illustrates a signal spectrogram for a fine search mode.

Example FIG. 12 is a picture showing an apparatus for locating inferior parts in power distribution line equipment in accordance with embodiments.

Example FIG. 13 is a picture showing a plurality of antennas disposed over a vehicle.

Example FIG. 14 is a block diagram illustrating an apparatus for locating inferior parts in power distribution line equipment in accordance with embodiments.

Example FIG. 15 is a block diagram for illustrating a wireless noise receiver, a signal processor, a frequency calibrator, an RF/AF controller, and a signal analyzer in detail.

Example FIG. 16 is a block diagram illustrating a signal processor in detail.

Example FIG. 17 shows an RF noise signal generated from an arcing gap.

Example FIG. 18 shows an RF noise signal having a high signal level.

Example FIG. 19 shows an RF noise signal generated from a peeled off insulation of a power cable on the top of a line post insulator.

Example FIG. 20 is a flowchart illustrating a frequency calibration method in accordance with embodiments.

Example FIGS. 21, 22, and 23 are flowcharts illustrating a method for locating inferior parts in power distribution line equipment in accordance with embodiments.

Example FIG. 24 is a flowchart illustrating operations of a fine search mode.

Example FIG. 25 is a flowchart illustrating operations of a directional search mode.

### DESCRIPTION

Hereinafter, an apparatus and method for locating inferior parts in power distribution line equipment in accordance with embodiments will be described. The apparatus for locating inferior parts in power distribution line equipment in accordance with embodiments scans environmental radio frequency (RF) noise signals such as public broadcasting signals, white noise signals, and pink noise signals in a predetermined patrol planning area for patrolling power distribution lines before patrolling the predetermined patrol planning area. The apparatus selects noise-free RF signals from a noise-free band that is not occupied by the environmental RF noise signals, continually receives the selected noise-free RF signals, converts currently received noise-free RF signals to an audio frequency signal, calculates variation of the currently received noise-free RF signals by comparing signal levels of a power frequency and harmonic frequencies in the audio frequency signal of the currently received RF signals with those of previously received RF signals, instead of comparing the signal level with a constant threshold value. The apparatus determines the number of frequencies having a changed signal level higher than the calculated variation. Then, the apparatus detects the inferior part of power distribution lines based on the calculated variation and the determined number of changed frequencies.

Since the apparatus for locating inferior parts in power distribution line equipment according to embodiments selects the noise-free RF signals by measuring the environmental RF noise signals and detects an RF signal generated from an inferior part based on the calculated variation and the number of frequencies having a signal level changed more than the calculated variation, the apparatus according to the embodiments can detect a very weak RF noise signal without including a plurality of receivers and complicated functions unlike other apparatuses according to the related art.

Power distribution lines operate like an antenna that receives and transmits almost all of the RF signals around the power distribution lines in a patrol planning area. In order to precisely detect a desired RF signal, the apparatus according to embodiments detects environmental RF noise signals in the patrol planning area before patrolling the power distribution lines in the patrol planning area and excludes the detected signal from RF signals to monitor.

After selecting noise-free RF frequencies by excluding the detected environment RF noise signals, the apparatus according to embodiments traces variation of the selected noise-free RF frequencies to locate an inferior part in power distribution equipment.

RF signals may be generated not only from inferior parts in power distribution line equipment but also from normal parts thereof. In the embodiments, RF signals generated from the inferior parts are determined based on variation of noise-free RF signals and the number of changed frequencies.

The apparatus for locating inferior parts in power distribution line equipment according to embodiments may further include a fine search function for accurately locating an inferior part generating an abnormal RF signal and a directional search function for displaying a direction to a signal source.

Hereinafter, the apparatus for locating inferior parts in power distribution line equipment according to embodiments will be described with accompanying drawings.

Example FIG. 14 illustrates an apparatus for locating inferior parts in power distribution line equipment in accordance with embodiments. Example FIG. 15 is a diagram for illustrating a wireless noise receiver, a signal processor, a frequency calibrator, an RF/AF controller, and a signal analyzer in detail. Example FIG. 16 is a block diagram illustrating a signal processor in detail.

As illustrated in FIG. 14, the apparatus for locating inferior parts in power distribution line equipments according to embodiments includes a wireless noise receiver 210, a signal processor 200, a frequency calibrator 230, an RF/AF controller 240, a GPS receiver 250, and a signal analyzer 260.

Before patrolling power distribution lines in a patrol planning area, the wireless noise receiver 210 collects environmental RF noise signals in the patrol planning area, selects noise-free RF signals by excluding the collected environmental RF noise signals. The wireless noise receiver 210 continually receives the selected noise-free RF signals while patrolling the power distribution lines in the patrol planning area and converts the received noise-free RF signals to an audio frequency signal.

The signal processor 220 receives the audio frequency signal from the wireless noise receiver 210. The signal processor 220 includes a low pass filter LPF 221 and a Fourier Transform unit 222 as shown in FIG. 16. The LPF 221 filters the audio frequency signal to pass frequency signals lower than about 800 Hz. The Fourier Transform unit 222 divides the filtered audio signal into a power frequency and harmonic frequencies thereof through a Fourier Transform unit 222 shown in FIG. 16. For example, when the a power frequency is 50 HZ, the filtered audio signal is divided into harmonic frequencies of 50 Hz, 100 Hz, 150 Hz, 200 Hz, and 250 Hz. When the power frequency is 60 Hz, the filtered audio signal is divided into harmonic frequencies of 60 Hz, 120 Hz, 180 Hz, 240 Hz, and 300 Hz. The signal processor 220 outputs the power frequency and the harmonic frequencies of the audio frequency signal.

The frequency calibrator 230 determines a noise-free band that is not occupied by the detected environmental RF noise signals and continually monitors multiple noise-free RF signals selected from the noise-free band by a group. The frequency calibrator 230 may include a frequency calibration program shown in FIG. 8.

The RF/AF controller 240 synchronizes an RF signal with an audio frequency (AF) signal and controls changing noise-free RF signals to monitor.

The global positioning signal (GPS) receiver 250 may include a positioning and visualization program. The GPS receiver 250 receives information about a patrol planning area and power distribution lines in the patrol planning, for example, from a new distribution information system (NDIS) of an electric power company, creates and displays an optimal patrolling path based on the received information, analyzes collected information from power distribution line equipment on the optimal patrolling path, records locations of power distribution line equipment generating a suspicious RF noise signal, a collection time thereof, a moving speed of a patrol vehicle, and a traveling direction, and displays recorded information.

The signal analyzer 260 receives the harmonic frequencies from the signal processor 220, calculates variation of each harmonic frequency, determines the number of changed harmonic frequencies, and detects an RF signal generated from an inferior part of power distribution line equipment.

The signal analyzer 260 may perform following functions.

The signal analyzer 260 receives the power frequency and the harmonic frequencies from the signal processor 220 and determines whether signal levels of the power frequency and the first harmonic frequency are greater than first and second threshold values TH1 and TH2. For example, the signal analyzer 260 receives the power frequency 60 Hz and the second to fifth harmonic frequencies 120 Hz, 180 Hz, 240 Hz, and 300 Hz as shown in FIG. 14.

The signal analyzer 260 determines whether a ratio of a sum of signal levels of the power frequency and the second to fifth harmonic frequencies and a signal level of an entire audio frequency signal is greater than a third threshold value TH3. When the ratio is greater than the third threshold value TH3 the signal analyzer 260 records related information and sounds a predetermined alarm.

The signal analyzer 260 compares signal levels of audio frequency signals that are converted from RF signals received through a plurality of antennas or a rotational antenna and searches a direction to a noise signal source based on the comparison result. When the ratio of power frequency and harmonic frequencies compared to an entire audio frequency signal is greater a predetermined threshold value, the signal analyzer 260 records related information and sounds a predetermined alarm.

As described above, an apparatus for locating inferior parts in power distribution line equipment according to embodiments detects an RF signal generated from an inferior part in power distribution line equipment by selecting multiple noise-free RF signals from a noise-free band, continually receiving the selected noise-free RF signals, and analyzing an audio frequency signal of the noise-free RF signals. Accordingly, the apparatus for locating inferior parts in power distribution line equipment according to embodiments has a simple structure compared to other related apparatuses.

The apparatus for locating inferior parts in power distribution line equipment according to embodiments can reselect a noise-free band in a predetermined area that is expected to have many environmental RF noise signals changed while patrolling the power distribution lines through monitoring frequency calibration. Therefore, the apparatus for locating inferior parts in power distribution line equipment according to embodiments can minimize influence of environmental factors in detecting a desired RF signal.

Accordingly, the apparatus for locating inferior parts in power distribution line equipment according to embodiments can detect an RF signal generated from an inferior part in power distribution lines irrespective of signal intensity.

The apparatus for locating inferior parts in power distribution line equipment according to embodiments may be mounted on a vehicle or carried by an operator, receive selected noise-free RF signals while traveling along a predetermined patrol path by the vehicle or on foot, and monitor audio frequency signals converted from the received noise-free RF signals.

Hereinafter, a method for locating inferior parts in power distribution line equipment in accordance with embodiments will be described with accompanying drawings.

Example FIG. 20 is a flowchart for describing the detection of environmental RF noise signals in a patrol planning area in accordance with embodiments. Example FIGS. 21, 22, and 23 are flowcharts for describing a method for locating inferior parts in power distribution line equipment in accordance with embodiments.

The method for locating inferior parts in power distribution line equipment according to embodiments may include detecting environmental RF noise signals in a patrol planning area before patrolling, detecting an inferior part of power distribution line equipment by continually receiving selected noise-free RF signals and monitoring audio frequency signals converted from the received noise-free RF signals, and selectively performing a fine search operation and a directional search operation when a predetermined alarm sounds by detecting inferior parts.

With reference to FIG. 20, the detecting of environmental RF noise signals in a patrol planning area will be described.

Power distribution lines are not only a noise source that generates RF noise signals but also an antenna that receives and retransmits environmental RF noise signals at the same time. Therefore, before patrolling a patrol planning area, environmental RF noise signals such as amplitude modulated (AM) signals are detected in the patrol planning area.

At step S1202, a band occupied by environmental RF noise signals in a patrol planning area is detected at a location at some distance from power distribution lines in the patrol planning area.

At step S1203, a band occupied by RF noise signals emitted from normal power distribution line equipment in the patrol planning area is detected at a location close to the power distribution lines in the patrol planning area. For example, the RF noise signals emitted from the power distribution lines may be amplitude modulated (AM) signals.

At step S1204, a band, which is higher than 1 MHz and not occupied by the environmental RF noise signals and the AM signals, is searched. For example, FIG. 8 shows bands 111 and 113 that are higher than 1 MH and not occupied by the environmental RF noise signals and the AM signals. At step S1025, it is determined whether this searched band is included in a public band or not. For example, FIG. 8 shows bands 112 included in the public band.

At step S1206, the searched band not included in the public band is set as a noise-free band to monitor and information about the noise-free band is stored in a database. As described above, the noise-free band is determined by detecting bands occupied by the environmental RF noise signals and the AM signals before patrolling power distribution lines in the patrol planning area.

Hereinafter, the detecting of an inferior part in power distribution line equipment by continually receiving selected noise-free RF signals and monitoring audio frequency signals converted from the received noise-free RF signals will be described.

At step S1101, a noise-free band in a patrol planning area is determined. The noise-free band is a band not occupied by environmental RF noise signals. For example, the noise-free band may be in a range of about 10 MH to about 600 MHz.

At step S1102, a plurality of noise-free RF signals are selected from the noise-free band and the selected noise-free RF signals are continually monitored as a group. For example, ten noise-free RF signals between about 58 MHz to about 281 MHz are selected from the noise-free band using a frequency calibration program shown in FIG. 8, and the selected noise-free RF signals are continually monitored as shown in FIG. 9.

For example, ten RF signals are consecutively received per each loop and audio frequency signals converted from the ten RF signals are analyzed by frequency. The spectrograms of FIGS. 10 and 11 show that most signals are generated from bands below about 300 MHz.

Although FIG. 10 shows a signal detected from a band higher than about 500 Hz (see a left top portion of the spectrogram of FIG. 10), it could be ignored. Red dots in the spectrogram of FIG. 10 clearly show that signals are strongly detected from a band of about 60 Hz and from a band of about 120 Hz which is a harmonic frequency thereof.

Accordingly, the wireless noise receiver 210 continually receives ten selected noise-free RF signals per one loop and converts the received noise-free RF signals to audio frequency signals. The signal processor 220 filters the audio frequency signal to pass frequencies thereof lower than about 800 MHz at step S1103 and transforms the passed audio frequency signals through an FFT. The signal analyzer 260 analyzes signal levels of the power frequency and the harmonic frequencies of the audio frequency signals at step S1104.

In more detail, the audio frequency signals outputted from the wireless noise receiver 210 are filtered to pass frequencies of the audio frequency signal lower than about 800 MHz as shown in a block 221 of FIG. 14, the passed audio signal is transformed through Fourier Transform as shown in a block 222 of FIG. 14 and divided into a predetermined power frequency and harmonic frequencies of the predetermined power frequency as shown in a block 223 of FIG. 14. The predetermined power frequency may be one of about 50 Hz and about 60 Hz. Signal levels of the power frequency and the harmonic frequencies are compared with signal levels of a power frequency and harmonic frequencies of a previous audio frequency signal. The previous audio frequency signal is an audio frequency signal demodulated from previously received noise-free RF signals. That is, signal levels of harmonic frequencies of currently received noise-free RF signals are compared with those of previously received noise-free RF signals.

For example, example FIG. 10 shows that a power frequency 60 Hz is strongly generated from 9^{th} frequency 271 MHz of ten frequencies (see a circle 118 in FIG. 10). In FIG. 11, an upper spectrogram shows monitoring received ten harmonic frequencies and a lower spectrogram shows monitoring the strongest harmonic frequency selected from the ten frequencies of the upper spectrogram. As described above, an inferior part in power distribution lines is detected by analyzing the spectrograms shown in FIGS. 10 and 11.

Example FIG. 11 shows a spectrogram used to analyze noise-free RF signals by selecting a fifth frequency 171 MHz and continually monitoring the selected fifth frequency in a 120 Hz fine search mode.

After analyzing the signal levels of frequencies, an occupancy rate of a power frequency and harmonic frequencies in an entire audio frequency signal may be calculated using an typical equation for calculating a signal-to-noise ratio.

SNR=20 log₁₀{(A_{f0}+A_{2f}+A_{3f}+A_{4f}+A_{5f})/A_{fall}} [Eq. 1]

In Eq. 1, A_{f0} indicates an amplitude value of a power frequency which may be referred to as a first harmonic frequency, A_{2f} indicates an amplitude value of a second harmonic frequency, A_{3f} indicates an amplitude value of a third harmonic frequency, A_{4f} indicates an amplitude value of a fourth harmonic frequency, A_{5f} indicates an amplitude value of a fifth harmonic frequency, and A_{fall} indicates an amplitude value of an entire audio frequency signal lower than about 800 Hz.

Example FIG. 9 shows a result of comparing an occupancy rate 116 of ten harmonic frequencies with a 60 Hz signal 115 and a 120 Hz signal 117. As shown, the 120 Hz signal is almost identical to that the occupancy rate 116 of the ten harmonic frequencies.

Referring back to FIG. 21, at step S1105, signal levels of a power frequency and a second harmonic frequency of the audio frequency signal converted from the currently received noise-free RF signal with signal levels of a power frequency and a second harmonic frequency of previously received noise-free RF signals. At step S1106, it is determined whether the signal levels of the power frequency and the second harmonic frequency are changed more than a first threshold value TH1 or not and whether the number of frequencies having a signal level changed more than the first threshold value TH1 is greater than a second threshold value TH2.

For example, when signal levels of a power frequency and a second harmonic frequency are analyzed in the morning or on a rainy day, the power frequency 60 Hz is analyzed at first through the steps S1105 and S1106. When signal levels of a power frequency and a second harmonic frequency are analyzed on a day with good weather conditions, the second harmonic frequency 120 Hz is analyzed at first through the steps S1105 and S1106.

When the number of frequencies changed more than the first threshold value TH1 is greater than the second threshold value TH2, signal-to-noise ratios of a power frequency and harmonic frequencies compared to an entire audio frequency signal is calculated at step S1107 as illustrated in FIG. 22. At step S1108, it is determined whether each of the calculated signal-to-noise ratios of the power frequency and the harmonic frequencies is greater than a third threshold value TH3 and whether the number of frequencies having the signal-to-noise ratio greater than the third threshold value TH3 is greater than the second threshold value TH2 or not. If the number of frequencies having the signal-to-noise ratio greater than the third threshold value TH3 is greater than the second threshold value TH2, a predetermined alarm sounds at steps S1109 and S1110 and related information are stored in a log at steps S1111 and S1112.

Alternatively, when the number of frequencies changed more than the first threshold value TH1 is smaller than the second threshold value TH2, signal-to-noise ratios of a power frequency and harmonic frequencies compared to an entire audio frequency signal is calculated at step S1107 as illustrated in FIG. 23. That is, signal-to-noise ratios of the harmonic frequencies may become abruptly increased although the received noise-free RF signals are not significantly changed. In this case, it is determined whether the calculated signal-to-noise ratios are greater than a fourth threshold value at step S1113. If the calculated signal-to-noise ratios are greater than a fourth threshold value, a predetermined alarm sounds at steps S1109 and S1110, and related information is recorded at steps S1111 and S1112. Then, a frequency calibration operation is performed again for changing noise-free RF signals to monitor.

Hereinafter, a fine search mode and a directional search mode will be described.

Example FIG. 24 is a flowchart illustrating operations of a fine search mode, and example FIG. 25 is a flowchart illustrating operations of a directional search mode.

When it is unclear which electric post generates a suspicious RF signal because a plurality of electric posts generate the suspicious RF signals, a fine search mode begins at step S1140. At step S1142, a frequency having the highest signal level is selected from harmonic frequencies and the selected harmonic frequency is continually monitored. At step S1142, it is determined whether the highest harmonic frequency of the audio frequency signal is 60 Hz or 120 Hz. If the highest harmonic frequency of the audio frequency signal is 60 Hz, the selected harmonic frequency is precisely analyzed through a 60 Hz monitor mode at step S1143. On the contrary, if the highest harmonic frequency of the audio frequency signal is 120 Hz, the selected harmonic frequency is precisely analyzed through a 120 Hz monitor mode at step S1144. At step S1145, an inferior part in power distribution lines is detected based on the result of the analysis.

At step S1146, the fine search mode ends after detecting the inferior part in power distribution lines and the normal search mode begins at step S1146.

Example FIG. 11 shows spectrograms used for a fine search mode. In FIG. 11, an upper spectrogram shows ten frequencies and a lower spectrogram shows a frequency having the highest signal level, which is selected from the ten frequencies of the upper spectrogram. An electric pole having an inferior part is detected by analyzing signal shapes in the lower spectrogram.

Example FIG. 25 shows operations of a directional search mode. A plurality of antennas may be disposed on a patrol vehicle toward the north, the south, the west, and the east. Or, an antenna may be rotationally disposed on a patrol vehicle. In this case, the directional search mode enables detecting a direction to an inferior part generating an RF noise signal. The wireless noise receiver 212 receives multiple RF signals through the plurality of antennas and converts the received RF signals to an audio frequency signal.

When the directional search mode is enabled at step S1151, a frequency having the highest signal level is selected from harmonic frequencies of the audio frequency signal and all of wireless noise receivers are set to monitor the selected harmonic frequency. At step S1152, a direction to an inferior part is determined by comparing the selected frequency signals that are received from different directions at the same time, and the direction is displayed on a screen.

Example FIG. 10 is a spectrogram of signals analyzed when two signals with the same frequency such as a 171 MHz signal are received through two antennas, such as a front antenna and a rear antenna, at the same time.

Example FIG. 17 shows an example of detecting an inferior part while patrolling power distribution lines using the apparatus for inferior parts in power distribution line equipment according to embodiments. Particularly, FIG. 17 shows detecting a gap discharge generating part of a suspension insulator by comparing a 120 Hz signal indicated by a green curve and an occupancy rate of harmonic frequencies indicated by a red curve.

Example FIG. 18 shows an example of detecting an inferior part of a combination insulator. Particularly, FIG. 18 shows detecting an RF noise signal generated from the inferior part of the combination insulator for a very short time around an electric pole. In this case, the inferior part is detected by the TH4 condition of step S1113 although the detected RF noise signal has frequencies satisfying the TH1 and TH2 condition of step S1106 and not satisfying the TH3 and TH2 condition of step S1108.

Example FIG. 19 shows an example of detecting an RF noise signal generated from an inferior insulated of a power cable on the top of a line post insulator. In this case, the inferior insulated covering can be detected because frequencies of an RF signal generated therefrom satisfy the TH1, TH2, and TH3 conditions. As shown, the apparatus for locating inferior parts in power distribution line equipment according to embodiments can detect an inferior part although it generates a very weak RF signal.

As described above, the apparatus for locating inferior parts in power distribution line equipment according to the embodiments can accurately detect an inferior part of power distribution line equipment although signal levels are changed because discharge characteristics of power distribution line equipment are changed according to temperature and humidity. Further the apparatus for locating inferior parts in power distribution line equipment according to the embodiments can detect an RF noise signal generated from an inferior part which causes arcing or corona discharge, regardless of weather conditions.

Instead of using a constant value, the apparatus for locating inferior parts in power distribution line equipment according to embodiments uses variations in RF noise signals and variations in occupancy rates of a power frequency and harmonic frequencies at the same time to detect an RF noise signal generated from an inferior part of power distribution line equipment.

The apparatus for locating inferior parts in power distribution line equipment according to embodiments also includes the fine search mode and the directional search mode in order to effectively detect an inferior part. The apparatus for locating inferior parts in power distribution line equipment according to embodiments may be mounted on a vehicle and can accurately determine an operation state of active power distribution line equipment without climbing up to the power distribution line equipment.

The apparatus and method for locating inferior parts in power distribution line equipment according to embodiments have following effects.

The apparatus and method for locating inferior parts in power distribution line equipment according to embodiments can accurately determine an operation state of active power distribution line equipment without climbing up to the power distribution line equipment.

Although a signal level of an RF noise signal is changed because the discharge characteristics of the power distribution line equipment are changed according to temperature and humidity, the apparatus and method for locating inferior parts in power distribution line equipment according to embodiments can detect the inferior part in power distribution line equipment, for example, inferior parts which cause arcing or continuous corona discharge irrespective of whether conditions.

Instead of using a constant value, the apparatus and method for locating inferior parts in power distribution line equipment according to embodiments uses variation in RF noise signals and variation in occupancy rates of a power frequency and harmonic frequencies at the same time to detect an RF noise signal generated from an inferior part in power distribution line equipment. Accordingly, accuracy of detecting inferior parts can be improved.

Since the apparatus and method for locating inferior parts in power distribution line equipment according to embodiments includes the fine search mode and the directional search mode, an inferior part can be more effectively detected.

The apparatus for locating inferior parts in power distribution line equipment according to embodiments may be mounted on a vehicle. Accordingly, an operation state of active power distribution line equipment can be more effectively determined without climbing up to the power distribution line equipment.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. An apparatus for locating inferior parts in distribution line equipment, comprising:
a wireless noise receiver for receiving environmental radio frequency noise signals at a predetermined patrol planning area for patrolling power distribution lines before patrolling the power distribution lines in the predetermined patrol planning area, receiving radio frequency noise signals emitted from normal power distribution line equipment in the predetermined patrol planning area, continually receiving multiple noise-free frequencies selected from a noise-free band while patrolling the power distribution lines in the predetermined patrol planning area, converting the received multiple noise-free frequencies into an audio frequency signal;
a signal processor for quantifying a power frequency and harmonic frequencies of the audio frequency signal;
a signal analyzer for calculating variation of the power frequency and the harmonic frequencies by comparing the signal levels of the power frequency and the harmonic frequencies with signal levels of a power frequency and harmonic frequencies of an audio frequency signal converted from a previously received noise-free RF signal, determining the number of changed frequencies based on the calculated variation, detecting a radio frequency noise signal generated from an inferior part of the power distribution line equipment based on the calculated variation and the number of changed frequencies; and
a frequency calibrator for receiving the received environmental radio frequency noise signals and the received radio frequency noise signals emitted from normal power distribution line equipment from the wireless noise receiver, determining the noise-free band that is not occupied by the measured radio frequency noise signals and the measured environmental radio frequency environmental noise signals, selecting the multiple noise-free frequencies from the noise-free band, and managing a list of the selected multiple noise-free frequencies.

2. The apparatus of claim 1, wherein the signal processor includes:
a low pass filter which filters the audio frequency signal from the wireless noise receiver to pass frequency signals lower than approximately 800 Hz; and
a Fast Fourier Transform unit for dividing the filtered signal from the low pass filter into the power frequency and the harmonic frequencies,
wherein the power frequency is one of approximately 50 Hz and approximately 60 Hz and the harmonic frequencies include second, third, fourth, and fifth harmonic frequencies.

3. The apparatus of claim 1, wherein the frequency calibrator groups the multiple noise-free radio frequency signals selected from the noise-free band into a monitoring group and continually monitors the monitoring group.

4. The apparatus of claim 1, further comprising:
a radio frequency/audio frequency controller for synchronizing a radio frequency signal with an audio frequency signal, receiving information on the selected multiple noise-free frequencies from the frequency calibrator, and controlling noise-free frequencies to monitor by transmitting a radio frequency signal selection command to the wireless noise receiver; and
a global positioning signal receiver, including a positioning information and visualization program, for recording information generated while patrolling power line equipment, and displaying related information.

5. A method for locating an inferior part of power distribution line equipment, comprising:
sequentially scanning radio frequency signals in a predetermined band at a predetermined location at a distance from the predetermined patrol planning area to determine environmental radio frequency noise signals and radio frequency noise signals including amplitude modulated noise signals emitted from normal power distribution line equipment in the predetermined patrol planning area, selecting multiple noise-free frequencies, and continually monitoring the selected multiple noise-free frequencies;
continually receiving the selected multiple noise-free radio frequency signals, converting the received multiple noise-free radio frequency signals to an audio frequency signal, quantifying a power frequency and harmonic frequencies of the audio frequency signals, calculating variation of the power frequency and the harmonic frequencies by comparing the signal levels of the power frequency and the harmonic frequencies with signal levels of a power frequency and harmonic frequencies of an audio frequency signal converted from a previously received noise-free RF signal, determining the number of changed frequencies based on the calculated variation, detecting a radio frequency noise signal generated from an inferior part in the power distribution line equipment based on the calculated variation and the number of changed frequencies; and
selectively performing a fine search mode and a directional search mode when the inferior part is detected.

6. The method of claim 5, wherein the continually received radio frequency signals are selected from a noise-free band which is not occupied by the scanned radio frequency noise signals and the scanned environmental radio frequency noise signals.

7. The method of claim 5, wherein in said detecting inferior parts in power distribution line equipment, the received multiple noise-free radio frequency signals are demodulated to an audio frequency signal, the audio frequency signal is filtered to pass a frequency signal lower than approximately 800 Hz, the filtered audio frequency signal is divided into a power frequency, second, third, fourth, and fifth harmonic frequencies, variation of a the power frequency, and the second, third, fourth, and fifth harmonic frequencies are calculated by comparing signal levels of the power frequency, and the second, third, fourth, and fifth harmonic frequencies with signal levels of a power frequency and harmonic frequencies of an audio frequency signal converted from previously received noise-free radio frequency signals, the number of changed frequencies in the power frequency, and second, third, fourth, and fifth harmonic frequencies are determined based on the calculated variation, and the inferior parts are detected based on the calculated variation and the number of the changed frequencies, wherein the power frequency is one of 50 Hz and 60 Hz.

8. The method of claim 5, wherein in said detecting inferior parts in power distribution line equipment, the received multiple noise-free radio frequency signals are demodulated to an audio frequency signal, the audio frequency signal is filtered to pass frequency signals lower than approximately 800 Hz, the filtered audio frequency signal is divided into a power frequency, second, third, fourth, and fifth harmonic frequencies, variation of a the power frequency, and the second, third, fourth, and fifth harmonic frequencies is calculated by calculating an occupancy rate of a sum of signal levels of the power frequency and the first, third, fourth, and fifth harmonic frequencies and a signal level of the filtered audio frequency signal and comparing the calculated occupancy rate with an occupancy rate of a power frequency and harmonic frequencies of an audio frequency signal converted from previously received noise-free radio frequency signals, the number of changed frequencies in the power frequency, and second, third, fourth, and fifth harmonic frequencies are determined based on the calculated variation, and the inferior parts are detected based on the calculated variation and the number of the changed frequencies, wherein the power frequency is one of 50 Hz and 60 Hz.

9. The method of claim 7, wherein a direction to an inferior part is detected by simultaneously receiving a frequency signal having a strongest signal level through a plurality of antennas or through rotating a rotational antenna and comparing the received frequency signals to each other, wherein the plurality of antennas are disposed toward different directions.

10. The method of claim 7, wherein an inferior part is detected by continually monitoring a frequency signal having a highest signal level in a suspected inferior part area and comparing the continually monitored frequency signals.

11. The method of claim 5, wherein said sequentially scanning radio frequency signals in a predetermined band includes:
determining an RF noise band occupied by the environmental RF noise signals of the patrol planning area at a location at a distance from power distribution lines in the patrol planning area;
determining an amplitude modulated noise band occupied by amplitude modulated noise signals emitted from power distribution lines in the patrol planning area at a location close to the power distribution lines; and
determining a noise-free band higher than approximately 1 MHz which is not occupied by the environmental RF noise signals and the amplitude modulated noise signals during said determining an RF noise band and said determining an amplitude modulated noise band, and determining whether the noise-free band is in a public band or not.
